(19) United States
(12) Patent Application Publication
(10) Pub. No.: US 2022/0199673 A1
(43) Pub. Date: Jun. 23, 2022

(54) MULTISPECTRAL IMAGE SENSOR AND METHOD FOR FABRICATION OF AN IMAGE SENSOR

(71) Applicant: ECOLE POLYTECHNIQUE FEDERALE DE LAUSANNE (EPFL), LAUSANNE (CH)

(72) Inventor: Assim Boukhayma, Neuchâtel (CH)

(21) Appl. No.: 17/262,409

(22) PCT Filed: Jul. 24, 2018
(86) PCT No.: PCT/EP2018/070004

§ 371 Date: Jan. 22, 2021

(51) Int. Cl. H01L 27/146

(52) U.S. Cl. CPC H01L 27/14645; H01L 27/14683; H01L 27/14634; H01L 27/14627

(57) ABSTRACT

The present invention relates to a multispectral image sensor having a pixel array for detecting images with light components in different wave-length ranges, comprising a plurality of imaging layers each embedded in a semiconductor substrate, wherein in each of the imaging layers an array of photodetecting regions is provided, wherein the photodetecting regions are configured with different absorption characteristics, wherein the imaging layers are stacked so that the photodetecting regions of the arrays are aligned, wherein the absorption characteristics allow a preferred absorption of light components of at least one predetermined wavelength range.

### TECHNICAL FIELD

The present invention relates to multispectral image sensors, particularly CMOS compatible image sensors. Furthermore, the present invention relates to processes for the fabrication of multispectral image sensors.

### TECHNICAL BACKGROUND

Multispectral image sensors are widely used in devices like mobile phones and digital cameras. Although, image resolution and sensitivity reached a high level, further applications arise which still have demands for higher resolution and image sensors operating in poor light conditions. These applications require higher sensitivity and compacting the functionality of multispectral imaging.

Multispectral image sensors are usually configured for a separated sensing of photons with different wavelength to enable the detection of color i.e. RGB images.

Typically, digital image sensors use Bayer filters to build color images. Bayer filtering is the standard for digital color imaging. In such a standard image sensor, the active pixel array of photodetectors of the digital image sensor is fabricated with a semiconductor having a bandgap energy smaller than the visible photon's energy. Hence, all impinging photons of the visible spectrum generate an electron hole pair with a given probability, and it is not possible to distinguish the color of the photon (its wavelength) from the electronic signal it generates in the semiconductor. Therefore, different color filters are implemented on top of neighboring pixels in order to separately detect the red, green and blue components of each pixel of the image. Post processing is then performed to associate an RGB value to each pixel using its neighboring pixels (demosaicing).

Image sensors with Bayer filters are limited due to the loss of at least ⅔ of the input signal due to the process of color filtering. In addition, detectable photons are lost due to the absorption within the color filters. Conceptionally, the effective resolution of such an image sensor concept is reduced with respect to the density of the pixels implemented on the image sensor, since the value of one RGB pixel is usually calculated using four neighboring pixels with different color filters.

As further known from US 2016/0064448, an alternative image sensor technology uses micro color splitters wherein the light is redirected instead of being filtered out by absorption. Micro-deflectors are used between two layers of micro-lenses on top of each pixel. The deflectors diffract one color to make it impinge on neighboring pixels. Such an approach uses the effective resolution in a similar way as the above Bayer filter image sensors and requires special post-processing consisting in special color splitters and top lenses.

US 2010/0157117 Al discloses an image sensor technology applying a vertical stacking of photosensitive regions in a single substrate for detecting blue, green and red pixels. The lower layers corresponding to the green and red pixels, however, are difficult to implement in a common CMOS fabrication process.

It is an object of the present invention to provide a multispectral image sensor with a higher sensitivity and a higher resolution. It is a further object of the present invention to further avoid aliasing and Moire effects in the process of demosaicing in the back processing of the acquired pixel data.

### SUMMARY OF THE INVENTION

One or more of these objects have been achieved by the multispectral image sensor according to claim 1 and the process for fabricating a multispectral image sensor according to the further independent claim.

Further embodiments are indicated in the dependent subclaims.

According to a first aspect a Multispectral image sensor having a pixel array for detecting images with light components in different wavelength ranges, comprising a plurality of imaging layers each embedded in a semiconductor substrate, wherein in each of the imaging layers an array of photodetecting regions is provided, wherein the photodetecting regions are configured with different absorption characteristics, wherein the imaging layers are particularly separately provided and stacked so that the photodetecting regions of the arrays are aligned, wherein the absorption characteristics define a preferred absorption of light components of at least one predetermined wavelength range.

It is an idea of the present invention to provide the multispectral image sensor having stacked imaging layers each separately fabricated and each having a plurality of pixels arranged in a pixel array. Each imaging layer is configured to have photodetecting regions representing the pixels (or part of each pixel) of the pixel array. The photodetecting regions are made of a semiconductor material wherein an impinging photon which is absorbed may generate an electron hole pair. The photodetecting regions are configured with a selected thickness to have a preferred sensitivity for photons of one or more wavelength ranges. Photons with wavelengths different therefrom may be transmitted through the respective photodetecting region to fall onto a photodetecting region of an imaging layer arranged beneath the upper imaging layer. So, while an upper imaging layer may be mainly sensitive for first wavelength range and allows to pass through wavelengths of the impinging light of other wavelengths, a lower imaging layer may have a photodetecting region mainly sensitive for light of the second (different from a first) wavelength.

For each pixel, the photodetecting regions of the upper imaging layer and the photodetecting regions of the lower layer are aligned so that an impinging photon arriving at one of the pixel of an upper layer is likely to be absorbed in the upper imaging layer if it has a wavelength of the first wavelength range or it is likely passed through the photodetecting region of the upper layer and absorbed in the photodetecting region of a lower imaging layer, if the photon has a wavelength in the second wavelength range.

Therefore, the photodetecting region of an upper imaging layer has to be provided by a semiconductor material having a thickness with respect to the photon direction which is adapted to preferably absorb photons of a respective first wavelength range and to preferably transmit photons having a wavelength which does not fall into the first wavelength range. By stacking a plurality of such separately made imaging layers, an incoming photon will be wavelength-selectively absorbed in the respective photodetecting region of one of the layers. So, it can be determined into which of the wavelength ranges of the different imaging layers, the wavelength of the detected photons most likely falls.

Such an arrangement allows to arrange the photodetecting regions of each imaging layer with a high resolution and without signal loss. Each of the photons impinging on a pixel structure is finally being absorbed in the photodetecting region of one of the imaging layers generating an electron hole pair therein. This results in an electronic signal which is associated to a preferred wavelength range so that it can be further processed. Furthermore, the process of demosaicing can be avoided so that Moire and aliasing effects do not occur. Moreover, as no color filters are used, the absorption in the filters can be avoided and the sensitivity can be substantially increased.

Further the photodetecting regions of at least the upper imaging layers may have absorption characteristics which allow a portion of light to transmit to the photodetecting regions of one of the lower imaging layers.

It may be provided that the photodetecting regions of each of the imaging layers have different thicknesses with respect to a direction perpendicular to the direction of the main surface of the respective imaging layer.

The aligned photodetecting regions of the plurality of imaging layers may have an increasing thickness of the photodetecting regions from the upper imaging layer which serves as a light impinging surface down to a lowest imaging layer.

According to an embodiment the imaging layers may be formed in a semiconductor substrate made of the same semiconductor material, such as silicon, or of at least two different semiconductor materials.

At least one of the imaging layers may be carried on a light transparent substrate, particularly made of glass or any other transparent materials which does not generate interface problems on the boundary to the semiconductor of the photodetecting region.

Particularly, the at least one imaging layer may be bonded to the light transparent substrate, particularly by means of wafer bonding.

Each imaging layer may have a light receiving surface which is provided with a micro-lens arrangement including micro-lenses each aligned to at least a part of the photodetecting regions.

Particularly, at least one micro-lens arrangement on one of the imaging layers is in contact with a light transparent substrate carrying of a neighboring one of the stacked imaging layers.

A fully transparent medium may be provided between the micro-lenses and the associated photodetecting region.

Moreover, three imaging layers may be stacked so that an upper imaging layer is configured with absorption characteristics to mainly absorb light up to wavelengths of between 450 nm to 550 nm, particularly to 500 nm, a middle imaging layer is configured with absorption characteristics to mainly absorb light up to wavelengths of between 550 nm to 650 nm, particularly to 600 nm, and a lower imaging layer is configured with absorption characteristics to mainly absorb light up to wavelengths of between 700 nm to 800 nm, particularly to 750 nm.

Furthermore, an upper imaging layer may have photodetecting regions with a thickness of 1.5−3 μm, a further imaging layer has photodetecting regions with a thickness of 3-8 μm, and a lower imaging layer has photodetecting regions with a thickness more than 9 μm, particularly more than 10 μm.

According to a further aspect an image sensor device comprising the above image sensor and a control unit configured to detect the light intensity of each pixel in each of the imaging layers wherein the light components for different wavelength ranges for each pixel are determined based on the detected light intensities for each pixel and on the absorption characteristics of the photodetecting layers of each imaging layer.

According to a further aspect, a method for fabricating an image sensor having a pixel array for detecting images in light components of different wavelength ranges is provided, comprising the steps of:
providing imaging layers with arrays of photodetecting regions forming pixels, wherein the photodetecting regions have differing absorption characteristics, wherein the absorption characteristics define a preferred absorption of light components of at least one predetermined wavelength range; and
stacking the imaging layers so that the photodetecting regions of the imaging layers are aligned.

Furthermore, the providing of the imaging layers may include bonding a semiconductor layer to a transparent layer.

Particularly, the semiconductor layer bonded to the transparent layer may be thinned by an etching or polishing process. The bonding process allows to handle semiconductor layers as thin as a few micrometers needed for providing the photodetecting regions to selectively absorb light of different wavelengths.

### BRIEF DESCRIPTION OF THE DRAWINGS

Embodiments are described in more detail in conjunction with the accompanying drawings in which:

FIG. 1 shows a schematic cross-sectional view of the multispectral image sensor according to an embodiment of the present invention;

FIG. 2 schematically shows a top view onto a substrate layer of the multispectral image sensor;

FIG. 3 shows a diagram illustrating the absorption depth in silicon as a function of the wavelength;

FIG. 4 shows a diagram illustrating the photon intensity as a function of the depth in silicon for blue, green and red;

FIGS. 5a to 5g show the process steps for fabricating a multispectral image sensor according to the present invention;

FIG. 6 shows a schematic cross-sectional view of the multispectral image sensor according to another embodiment of the present invention; and

FIG. 7 shows a packaged imaging sensor.

### DESCRIPTION OF EMBODIMENTS

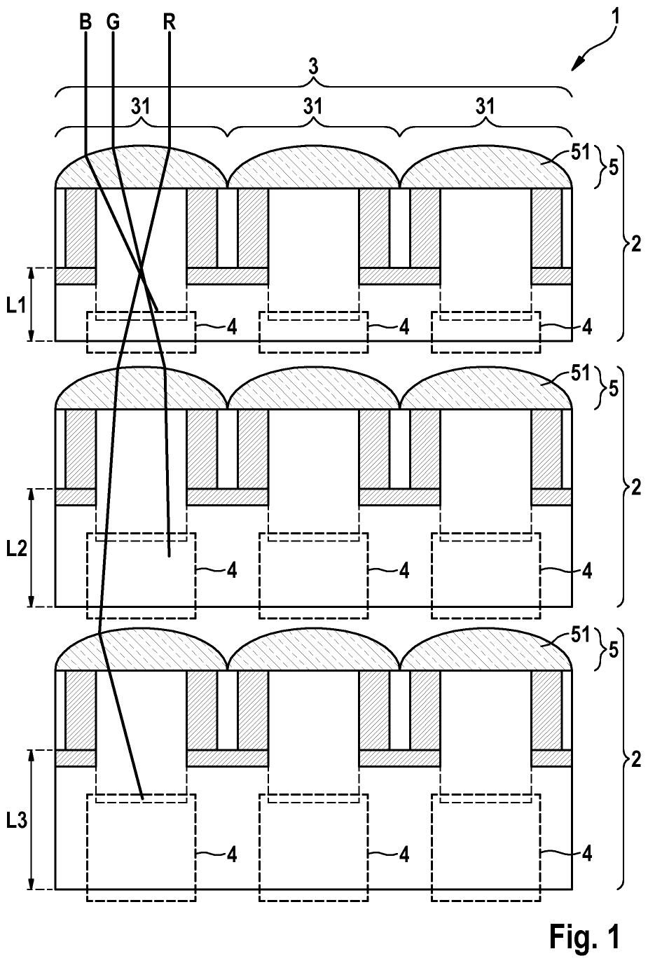

FIG. 1 schematically shows a cross-sectional view through a portion of multispectral image sensor 1 with three stacked layers 2 including a first, second and third imaging layer L1, L2, L3. Each of the imaging layers L1, L2, L3 has an array 3 of neighboring pixels 31 being distanced so that the arrays 3 of pixels 31 of the layers 2 have identical grids.

The stacked layers 2 are integrated in or formed by a semiconductor substrate. As semiconductor material for the semiconductor substrate many different types of semiconductor materials are possible. For ease of description the invention is further described with silicon as a preferred semiconductor material while other semiconductor materials which are suitable for photon detection can be applied for implementation of the present invention as well. Usage of silicon has the advantage that it can be processed by well-known technology processes such as a CMOS process.

Each pixel of each layer 2 provides a photosensitive region 4 which is configured to preferably absorb photons with a wavelength in a dedicated wavelength range and to preferably transmit photons with higher wavelengths. The photosensitive region 4 may include a pn junction, a PIN-diode or the like wherein an absorbed photon likely generates an electron hole pair. On absorption, the bandgap of the pn junction separates an electron and a hole of a generated electron hole pair resulting in an electrical potential to be measured by a sensing circuitry.

The imaging layers 2, L1, L2, L3 are stacked so that the arrays 3 of pixels and the photodetecting regions 4 are aligned along a direction substantially vertical to the surfaces of the layers, i.e. the photosensitive regions 4 of each layer 2 are aligned to each other. So, each of the photons impinging substantially perpendicularly on top of the upper first imaging layer L1 onto a pixel 31 is either absorbed in the respective photosensitive region 4 of the first imaging layer L1 or passed through towards the photosensitive region 4 of the second imaging layer L2. Each of the passing photons is then either absorbed in the respective photosensitive region 4 of the second imaging layer 2 or passed through towards the photosensitive region 4 of the third imaging layer L3. The respective photosensitive region 4 of the third imaging layer L3 may be configured to absorb each of the remaining photons.

Above arrangement results in the effect that each of the photons impinging onto the pixel of the image sensor 1 will be absorbed in one of the photodetecting regions 4 thereby generating an electrical signal in one of the layers L1, L2, L3. Each of the photodetecting regions 4 of the different layers have predetermined absorption characteristics so that likelihood and wavelength of the absorption of photons is known.

Each array 3 of pixels 31 of each imaging layer 2 (L1, L2, L3) may have a micro-lens arrangement 5. The micro-lens arrangement 5 has micro-lenses 51 which are aligned to a respective (associated) photosensitive region 4 so that a photon impinging on the pixel area of the respective imaging layer L1, L2, L3 is directed to the associated photosensitive region 4. The micro-lenses 51 may be arranged with a specified distance from the photodetecting region 4 wherein between the micro-lenses 51 and the associated photodetecting regions 4 a fully light transmitting medium such as SiN₂, Si0₂ or the like is included. The micro-lenses 51 may be configured with a focus which corresponds to the distance between the micro-lens and the respective photodetecting region 4.

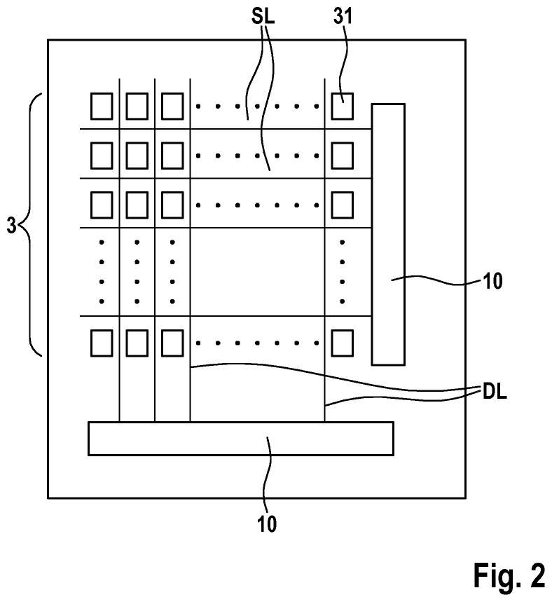

FIG. 2 shows schematically a top view on one of the imaging layers 2 to illustrate the grid of the array 3 of pixels 31. Between the pixels 31 select lines SL are located for selecting one row of pixels for reading out with sense amplifiers via data lines DL. Circuitry 10 for selecting the rows and for reading out data is arranged aside of the array 3 as commonly known in the art. Each of these layers L1, L2, L3 shall be designed for detecting a part of the photons which are selectively detected by a wavelength range and a given likelihood of absorption.

The thickness of the photosensitive regions 4 in each imaging layer L1, L2, L3 is configured depending on the absorption depth in silicon as a function of the wavelength of the respective photon. The absorption depth indicates the depth from the surface on which the photon impinges where the light intensity has fallen to 36% (1/e) of its original value. That means that the absorption likelihood of a photon is about 64% (1−1/e). An absorption depth of, for example, 1 μm means that the light intensity has fallen to 36% (1/e) of its original value.

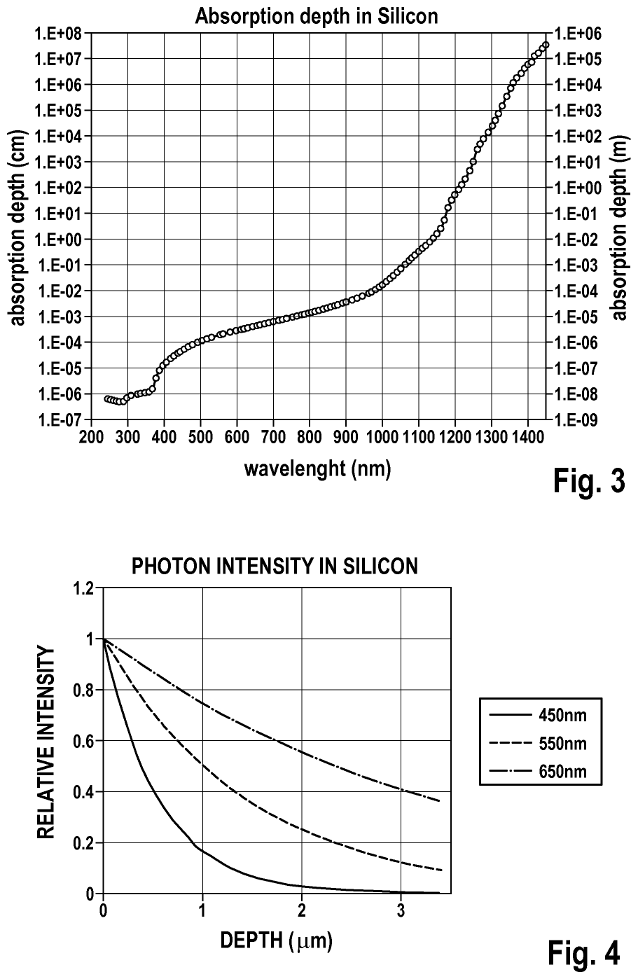

As shown in the diagram of FIG. 3, the absorption depth in silicon as an exemplary semiconductor is shown as a function of the wavelength. It can be seen that the characteristics of photon absorption strongly depends on the wavelength of the impinging photons, wherein the higher the wavelength the larger the absorption depth (with respect to the surface on which the photon impinges). Vice versa, the lower the wavelength, the lower is the absorption depth in silicon.

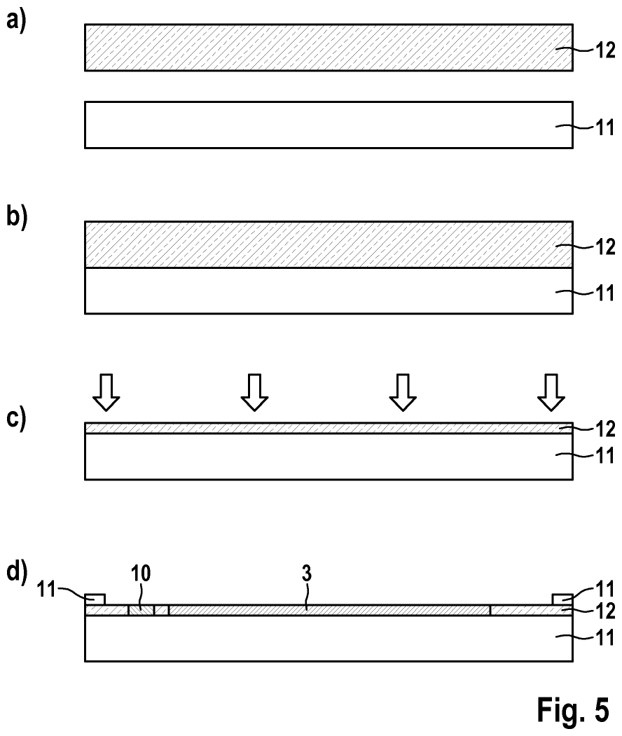

This effect can also be illustrated by the diagram as shown in FIG. 4 wherein the photon intensity as a function of the depth in silicon for blue, green and red light (photons) is shown. Particularly, FIG. 4 shows the relative intensity over the depth in micrometers in silicon. Here, it can be seen that the absorption of photons in lower depth of the photosensitive region 4 is higher for lower wavelength.

Substantially, the light absorption in silicon is described by the Beer-Lambert law wherein the light intensity at a depth L in silicon corresponds to

I(L)=I₀e^{-α(λ)L}

wherein I(L) is the remaining intensity in depth L of light impinging with an intensity I₀, and

$$\frac{1}{α} ( λ )$$

is the absorption depth in silicon for a wavelength λ.

The photosensitive regions 4 of the different layers 2 of the pixel arrays are configured with different thicknesses to mainly absorb photons of different wavelength ranges. Therefore, based on the light absorption properties of silicon, a vertical stacking of pixels with wisely chosen thicknesses of the photodetecting regions 4 can be an efficient way to perform color imaging or multispectral imaging in general. By exploiting the dependency of absorption depth on the wavelength of impinging light onto the thickness of the photosensitive regions 4 of the different layers 2, photons of different colors can be selectively (preferredly) absorbed in different layers 2 of the image sensor 1.

In an example of three layers 2, the thickness of the photosensitive region 4 of the upper first layer L1 can be chosen as 2 μm corresponding to a wavelength range of blue light, the thickness of the photosensitive region 4 of the second layer L2 as 4 μm corresponding to a wavelength range of green light and the thickness of the photosensitive region 4 of the third layer L3 can be selected as more than 10 μm corresponding to a wavelength of red light. According to the following table, which indicates the absorption ratios R of light in the specified wavelength range, it can be seen that most of the blue component B of photons gets absorbed in the upper first layer L1 (having a thickness of 2 μm of the photosensitive region) while the absorption of the green component G of the photons is mainly split between the photosensitive regions 4 of the first and the second imaging layer L1, L2. Although some portion of the green component G of the photons is absorbed in the first and third imaging layers L1, L3 the largest portion of the light arriving at the second layer L2 (having a thickness of 4 μm of the photosensitive region) is the green component. Although some portion of the red component R of the photons are absorbed in the first and second imaging layers L1, L2 the remaining half of the red component R is absorbed in the lowest third imaging layer L3 (having a thickness of 10 μm of the photosensitive region).

| | | Thickness | | |
|---|---|---|---|---|
| | | 2 μm | 4 μm | >10 μm |
| Wavelengths | Red component ~700 nm | 0.2 R | 0.3 R | 0.5 R |
| | Green component ~546 nm | 0.5 G | 0.4 G | 0.1 G |
| | Blue component ~436 nm | 0.9 B | 0.1 B | |

By knowing the absorption ratios R and the absolute intensities of light detected in each of the imaging layers L1, L2, L3 it is possible to calculate an intensity of each component R, G, B corresponding to wavelength ranges of the three imaging layers L1, L2, L3. In other words, by solving the linear equations of

I(L1)=0.2R+0.5G+0.9B

I(L2)=0.3R+0.4G+0.1B

I(L3)=0.5R+0.1G

with I the total intensity of light detected in the given layer L1, L2, L3 the blue, green and red component B, G, R can be determined.

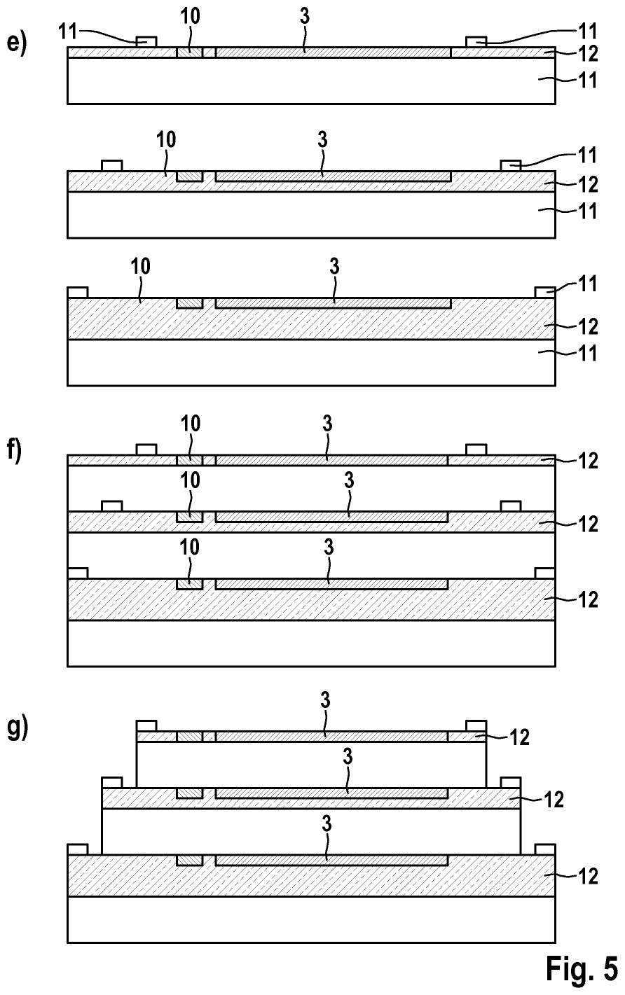

In FIG. 5, a process for fabricating a single substrate layer 2 with an array 3 of pixels 31 is illustrated. The substrate layer is fabricated with pixels each formed by a thinned photodetecting region 4.

As shown in FIG. 5a a transparent substrate 11, such as SiO₂, and a semiconductor substrate 12 which may be a p-silicon substrate are provided. The transparent substrate 11 may be provided with a thickness /stability so that the transparent substrate 11 can serve as a carrier for the semiconductor substrate 12 as the semiconductor substrate 12 will be provided with a very low thickness of less than 10 μm.

As shown in FIG. 5b, the substrates are cleaned and bonded, for example a well- known waferbonding process can be used in a way that does not introduce any intermediate layer keeping the interface between the substrates fully transparent to light. So, it is obtained a silicon-to-glass wafer.

FIG. 5c illustrates a thinning process wherein the semiconductor layer 12 (silicon) is thinned to reach the desired silicon thickness. Thinning can be carried out by standard non-isotropic etching processes, polishing processes or the like. It becomes apparent that the transparent layer 11 serves as a carrier as the low mechanical stability of the thinned semiconductor layer 12 does not allow further handling by itself. Therefore, bonding the semiconductor layer 12 to the transparent layer 11 increases the mechanical stability of the thinned semiconductor layer 12 and allows silicon thinning without having an ultra-thin wafer. Further the transparent layer 11 does not block any photons transmitted through photodetecting regions 4 of upper imaging layers L1, L2 from reaching the photodetecting regions 4 of lower layers L2, L3.

As shown in FIG. 5d, the thinned silicon-on-glass wafer is then processed to implement photodetecting regions 4 of the array 3 of pixels 31 and electronic circuity as shown in FIG. 2, as well contact pads 11 for electrical connecting the respective layer in a conventional manner which is well known from a standard processing of image sensors. Further, optionally micro-lenses can be arranged on top of all imaging layers L1, L2, L3. The micro-lenses are made of silicon oxide covering the metal wiring of the imaging layers L1, L2, L3.

FIG. 5e shows that multiple silicon-on-glass substrate imaging layers can be processed with different imaging layer thicknesses. Possible thicknesses are indicated above.

As shown in FIG. 5f, these layers 2 can be stacked to form a stacked multiple layer image sensor for color imaging or multispectral light sensing in general. The stacking is performed so that the photodetecting regions 4 and the array of pixels are aligned.

The aligning is performed so that an impinging photon can pass through the layer stack down to the photodetecting region 4 of the lowest layer L3.

In FIG. 5g edge parts of layers are etched to make contact pads of lower imaging layers in the stack accessible.

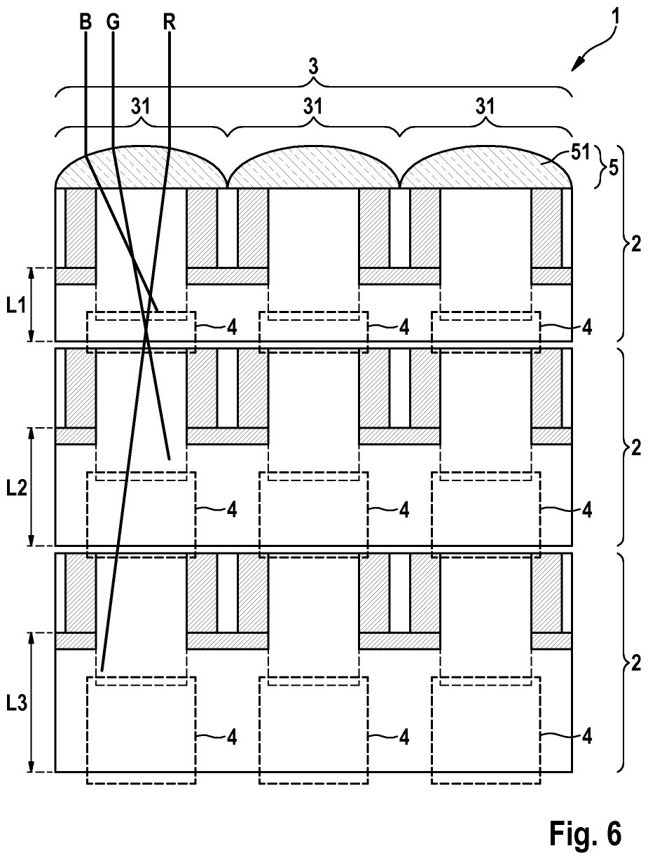

In FIG. 6 it is shown an alternative multispectral image sensor wherein micro- lenses are only provided on top of the stacked multiple layer image sensor. The micro-lenses are made of silicon oxide covering the metal wiring of the upper imaging layer while omitting arranging the micro-lenses of the other layers in step of FIG. 5d.

Substantially, the bonding pads of the layers are arranged close to the edge of the layers. The layers are provided with varying sizes so that when stacking a pyramid like structure is achieved allowing free access to bonding pads with the layer's area decreasing towards the upper layer.

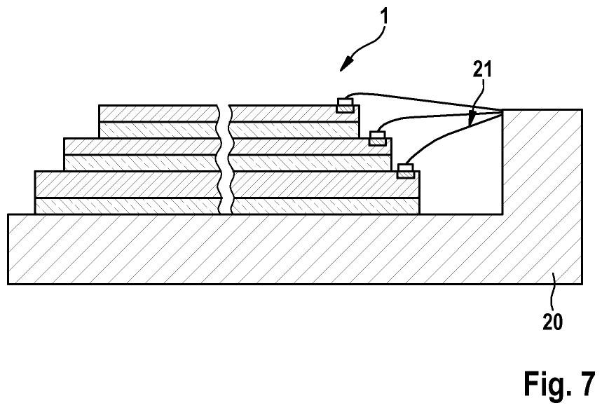

FIG. 7 shows an example of the image sensor 1 which is wire-bonded by bonding wires 21 in a package 20.

1. Multispectral image sensor having a pixel array for detecting images with light components in different wavelength ranges, comprising a plurality of imaging layers each embedded in a semiconductor substrate, wherein in each of the imaging layers an array of photodetecting regions is provided, wherein the photodetecting regions are configured with different absorption characteristics, wherein the imaging layers are stacked so that the photodetecting regions of the arrays are aligned, wherein the absorption characteristics define a preferred absorption of light components of at least one predetermined wavelength range.

2. Image sensor according to claim 1, wherein the photodetectin regions of at least the upper imaging layers have absorption characteristics which allow a portion of light to transmit to the photodetecting regions of one of the lower imaging layers.

3. Image sensor according to claim 1, wherein the photodetecting regions of each of the imaging layers have different thicknesses with respect to a. direction perpendicular to the direction of the main surface of the respective imaging layer.

4. image sensor according to claim 3, wherein the aligned photodetecting regions of the plurality of imaging layers have an increasing thickness of the photodetecting regions from the upper imaging layer which serves as a light impinging surface down to a lowest imaging layer.

5. Image sensor according to any of the claim 1, wherein the imaging layers are formed in a semiconductor substrate made of the same semiconductor material, such as silicon, or of at least two different semiconductor material s.

6. Image sensor according to claim 1, wherein at least one of the imaging layers is carried on a light transparent substrate, particularly made of glass.

7. Image sensor according to claim 6, wherein the at least one imaging layer is bonded to the light transparent substrate, particularly by means of wafer bonding.

8. Image sensor according to claim 1, wherein each imaging layer has a light receiving surface which is provided with a micro-lens arrangement including micro-lenses each aligned to at least a part of the photodetecting regions.

9. Image sensor according to claim 8, wherein at least one micro-lens arrangement on one of the imaging layers is in contact with a light transparent substrate carrying of a neighboring one of the stacked imaging layers.

10. Image sensor according to claim 8, wherein a fully transparent medium is provided between the micro-lenses and the associated photodetecting region.

11. Image sensor according to claim 1, wherein three imaging layers are stacked so that an upper imaging layer is configured with absorption characteristics to mainly absorb light up to wavelengths of between 450 nm to 550 nm, particularly to 500 nm, a middle imaging layer is configured with absorption characteristics to mainly absorb light up to wavelengths of between 550 nm to 650 nm, particularly to 600 nm, and a lower imaging layer is configured with absorption characteristics to mainly absorb light up to wavelengths of between 700 nm to 800 nm, particularly to 750 nm.

12. Image sensor according to claim 1, wherein an upper imaging layer has photodetecting regions with a thickness of 1.5-3 μm, a further imaging layer has photodetecting regions with a thickness of 3-8 μm, and a lower imaging layer has photodetecting regions with a thickness more than 9 μm, particularly more than 10 μm.

13. Image sensor device comprising an image sensor according to claim 1 and a control unit configured to detect the light intensity of each pixel in each of the imaging layers wherein the light components for different wavelength ranges for each pixel are determined based on the detected light intensities for each pixel and on the absorption characteristics of the photodetecting layers of each imaging layer.

14. Method for fabricating an image sensor having a pixel array for detecting images in light components of different wavelength ranges, comprising:
providing separate imaging layers with arrays of photodetecting regions forming pixels, wherein the photodetecting regions have differing absorption characteristics, wherein the absorption characteristics define a preferred absorption of light components of at least one predetermined wavelength range; and
stacking the imaging layers so that the photodetecting regions of the imaging layers are aligned.

15. Method according to claim 14, wherein the providing of the imaging layers include bonding a semiconductor layer to a transparent layer.

16. Method according to claim 15, wherein the semiconductor layer bonded to the transparent layer is thinned by an etching or polishing process.

17. Multispectral optical sensor having a pixel array for detecting light components in different wavelength ranges, comprising a plurality of layers each embedded in a semiconductor substrate, wherein in each of the layers an array of photodetecting regions is provided, wherein the photodetecting regions are configured with different absorption characteristics, wherein the layers are stacked so that the photodetecting regions of the arrays are aligned, wherein the absorption characteristics define a preferred absorption of light components of at least one predetermined wavelength range.
